(19) United States
(12) Patent Application Publication
(10) Pub. No.: US 2026/0182470 A1
(43) Pub. Date: Jun. 25, 2026

(54) Surface Mount Technology Technique Using Self-Spaced Components

(71) Applicant: Apple Inc., Cupertino, CA (US)

(72) Inventors: Suk-Kyu Ryu, San Jose, CA (US); Saumya K. Gandhi, San Francisco, CA (US); Wei Chen, San Jose, CA (US); Jie-Hua Zhao, Cupertino, CA (US); Luize Scalco de Vasconcelos, San Jose, CA (US)

(21) Appl. No.: 18/988,300

(22) Filed: Dec. 19, 2024

(51) Int. Cl. H01L 23/498; H01L 23/00; H01L 23/31; H01L 23/538; H01L 25/065; H01L 25/16

(52) U.S. Cl. CPC H10W 90/701; H10W 70/60; H10W 70/611; H10W 70/65; H10W 74/117; H10W 90/00; H10W 90/401; H10W 90/724

(57) ABSTRACT

Electronic modules are described that include a plurality of deflectors to mitigate the risk of solder bridging. In an embodiment, an electronic module includes an IC structure mounted on a module substrate, where the IC structure includes an IC die bonded to a routing layer and encapsulated by a gap fill material. Further, a plurality of deflectors may be located directly under one or more points or regions where a standoff distance between the back side of the routing layer and the top side of the module substrate is lowest. In such instances, the plurality of deflectors may be bonded the back side of the routing layer and/or the top side of the module substrate at the low points or regions.

### BACKGROUND

### Field

Embodiments described herein relate to semiconductor packaging, more particularly to surface mount technology.

### Background Information

Surface mount technology plays a significant role in printed circuit board (PCB) assembly, where manufacturers attempt to pack more functionality into smaller and sleeker devices. Flip chip bonding is a type of surface mount technology that directly connects a chip to a substrate (e.g., PCB) through solder bumps on the underside of the package, thereby minimizing the length of the electrical path and maximizing the density of electrical connections. In addition, high performance chips may also require multiple passive components on the underside of the package to optimize performance by managing power consumption, improving electrical performance, enhancing thermal dissipation, etc.

### SUMMARY

Embodiments describe electronic modules that include an integrated circuit (IC) structure mounted to the top side of a module substrate. Further, the IC structure includes an IC die, a gap fill material that encapsulates the IC die and a routing layer, where the IC die is bonded to a top side of the routing layer and the back side of the routing layer includes an array of solder joints. In embodiments, the electronic module may also include a plurality of deflectors located at one or more points or regions where the standoff distance between the back side of the routing layer and the top side of the module substrate is lowest.

### BRIEF DESCRIPTION OF THE DRAWINGS

FIG. 1A is a schematic cross-sectional side view illustration of an electronic module that includes a plurality of deflectors bonded to an IC structure in accordance with embodiments.

FIG. 1B is a schematic cross-sectional side view illustration of an electronic module that includes a plurality of deflectors bonded to a module substrate in accordance with embodiments.

FIG. 2A is a close-up view of a schematic cross-sectional side view illustration of solder bridging for an IC structure with concave curvature.

FIG. 2B is a close-up view of a schematic cross-sectional side view illustration of solder bridging for an IC structure with convex curvature.

FIG. 2C is a close-up view of a schematic cross-sectional side view illustration of solder bridging for an IC structure with both concave and convex curvature.

FIG. 3A is a close-up view of a first deflector bonded to the IC structure in accordance with embodiments.

FIG. 3B is a close-up view of a second deflector bonded to the IC structure in accordance with embodiments.

FIG. 3C is a close-up view of a third deflector bonded to the IC structure in accordance with embodiments.

FIG. 3D is a close-up view of a fourth deflector bonded to the module substrate in accordance with embodiments.

FIG. 3E is a close-up view of a fifth deflector bonded to the module substrate in accordance with embodiments.

FIG. 4A is a schematic cross-sectional side view illustration of an electronic module that includes a plurality of deflectors bonded to both an IC structure and a module substrate in accordance with embodiments.

FIG. 4B is a bottom view of an electronic module that includes a plurality of deflectors bonded to both an IC structure and a module substrate in accordance with embodiments.

### DETAILED DESCRIPTION

The flip chip bonding process may involve the simultaneous application of heat and pressure (e.g., thermocompression) to create reliable electrical and mechanical connections between the solder bumps of the package and the contact pads of a substrate (e.g., PCB). However, it has been observed that warpage of the package may have an adverse effect on the quality and reliability of the flip chip bonds. For example, due to the curvature of a warped package, the package may have solder bumps located at low points and solder bumps located at high points, where the solder bumps at the low points are closer to the contact pads of the substrate than the solder bumps at the high points. If the warped package is not compressed enough, the solder bumps at the high points of the package may not contact the contact pads of the substrate, resulting in “solder openings.” To avoid solder openings at the high points, the package may undergo additional compression to cause the solder bumps at the high points to contact the contact pads of the substrate. However, the additional compression required to avoid solder openings at the high points may cause the solder bumps at the low points to “overshoot” their nominal bond/joint height, which may ultimately cause the solder bumps at the low points to collapse or merge into one another. This is typically referred to as “solder bridging,” which can cause short circuits that lead to the malfunction or even failure of the package. Further, compressive stresses at elevated temperature may cause solder joints to undergo creep damage by which the solder joints slowly “creep” out of shape over time and potentially weaken their connection with the module substrate.

In embodiments, an electronic module may include an IC structure mounted to a module substrate. The IC structure may include an IC die, a gap fill material that encapsulates the IC die and a routing layer, where the IC die is bonded to the top side of the routing layer and the back side of the routing layer includes an array of solder joints. Further, the electronic module may include a plurality of deflectors located at one or more low points (or low regions that surround the low points) of the IC structure. In such instances, a low point or region may be defined as a point or region where the standoff distance between the back side of the routing layer and the top side of the module substrate is lowest. In this way, the plurality of deflectors effectively replaces the solder joints at locations susceptible to solder bridging based on a given curvature or warpage characteristic of the IC structure, thereby mitigating the risk of solder bridging. In addition, the thickness of the plurality of deflectors may be controlled to further mitigate the risk of solder bridging, where the thickness of each of the plurality of deflectors may be between 50-80% of the standoff distance between the back side of the routing layer and the top side of the module substrate. Further, the plurality of deflectors may also provide an added mechanical benefit by reducing the compressive stresses on the solder joints surrounding the plurality of deflectors, thereby mitigating creep damage for such solder joints.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “to”, “between”, and “on” as used herein may refer to a relative position of one layer with respect to other layers. One layer “above”, or “on” another layer or bonded “to” or in “contact” with another layer may be directly in contact with the other layer or may have one or more intervening layers. One layer “between” layers may be directly in contact with the layers or may have one or more intervening layers.

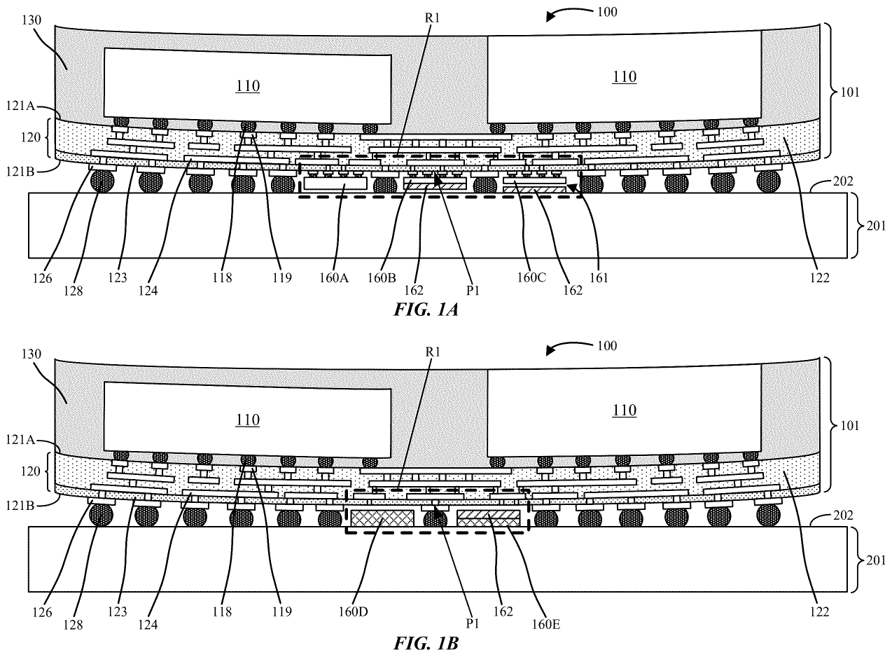

Referring now to FIGS. 1A-1B, FIG. 1A is a schematic cross-sectional side view illustration of an electronic module 100 that includes a plurality of deflectors bonded to an integrated circuit (IC) structure in accordance with embodiments, FIG. 1B is a schematic cross-sectional side view illustration of an electronic module 100 that includes a plurality of deflectors bonded to a module substrate in accordance with embodiments. In embodiments, an electronic module may include an IC structure mounted to a module substrate (e.g., printed circuit board (PCB), interposer, etc.). In the example of FIGS. 1A-1B, electronic module 100 includes IC structure 101 mounted to module substrate 201. IC structure 101 may be a wafer level multi-chip module in which multiple IC dies (e.g., system-on-chip (SOC), dynamic random-access memory (DRAM), etc.) are bonded by any suitable method (e.g., chip first, chip last, hybrid bonding, etc.) to a routing layer and encapsulated by a gap fill material. In some embodiments the gap fill material may include a molding compound (e.g., epoxy molding compound, etc.) to encapsulate the IC dies, whereas in other embodiments the gap fill material may include other suitable material that may be deposited rather than molded to encapsulate the IC dies (e.g., oxides, silicon, etc.). In the example of FIGS. 1A-1B, multiple IC dies 110 are bonded to routing layer 120 and encapsulated by gap fill material 130.

In further reference to FIGS. 1A-1B, routing layer 120 may be formed by a layer-by-layer process, and may be formed using thin film technology. For example, routing layer 120 may be formed on a reconstituted wafer or panel that includes diced/encapsulated dies in accordance with a chip first approach, or on a carrier substrate, for example, where the dies may be bumped and bonded to routing layer 120 in accordance with a chip last approach. Further, routing layer 120 may also include one or more redistribution lines 124 embedded in one or more dielectric layers 122. The one or more dielectric layers 122 may be formed by standard deposition techniques (e.g., lamination, spin coating, spray coating, physical vapor deposition, chemical vapor deposition, etc.) and may include suitable materials to provide features such as isolating interconnect levels, stress buffering, etc. The redistribution lines 124 (e.g., embedded traces) may include, but are not limited to, metallic materials such as copper, titanium, nickel, gold, and combinations or alloys thereof. Further, redistribution lines 124 may also include contact pads to connect to other devices, such as contact pads 119 on top side 121A of routing layer 120 that connect to solder joint 118 of IC die 110 in the examples of FIGS. 1A-1B. Further still, routing layer 120 may include a passivation layer, such as passivation layer 123 (e.g., low temperature polyimide (“LTPI”), etc.) on back side 121B of routing layer 120, where back side 121B of routing layer 120 may also include under bump metallization (UBM) pads 126 and solder joints 128 that bond IC structure 101 to module substrate 201.

It has been observed that IC structures may have residual warpage. For example, bonding processes (e.g., flip chip bonding, hybrid bonding, etc.) may cause stress in the dielectric layers of an IC structure, which may in turn cause a certain level of intrinsic strain in the IC die. Such stresses and strains may cause residual warpage in the IC structure, which may cause some solder bumps to be located at low points and other solder bumps to be located at high points relative to the top surface of the module substrate. When flip chip mounting IC structures to module substrates (which may also have residual warpage), solder bumps located at the low points or regions of the IC structure may undergo additional stresses since the bonding process (e.g., thermocompression bonding) must “overshoot” the nominal bond/joint height of the solder bumps located at the low points or regions in order for the solder bumps located at the high points or regions to contact the module substrate. Such overshoot may cause laterally adjacent solder bumps located at the low points or regions to collapse or merge into each other, which may also be termed “solder bridging.”

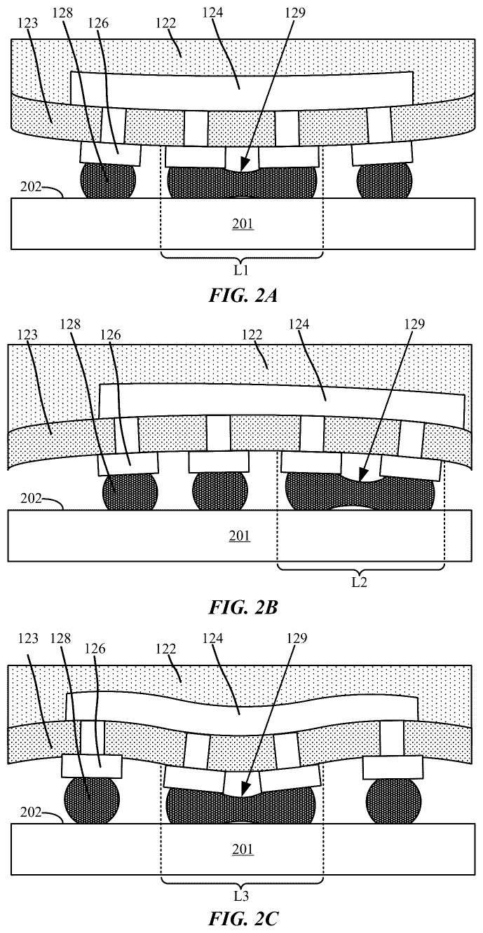

Referring now to FIGS. 2A-2C, FIG. 2A is a close-up view of a schematic cross-sectional side view illustration of solder bridging for an IC structure with concave curvature; FIG. 2B is a close-up view of a schematic cross-sectional side view illustration of solder bridging for an IC structure with convex curvature; FIG. 2C is a close-up view of a schematic cross-sectional side view illustration of solder bridging for an IC structure with both concave and convex curvature. The examples of FIGS. 2A-2C show low points or low regions of a conventional IC structure where solder joints may be susceptible to solder bridging. As shown, IC structure 101 is bonded to top side 202 of module substrate 201, where IC structure 101 includes redistribution lines 124 embedded in dielectric layer 122, passivation layer 123, UBM pads 126 and solder joints 128 similar to FIGS. 1A-1B. Further, different curvatures of the IC structure may result in solder bridging at different locations along the back side of the routing layer. In the example of FIG. 2A, IC structure 101 has a concave curvature or a “smile” shape, where solder bridging (e.g., solder bridge 129) may occur at a central point or region, such as region L1. In the example of FIG. 2B, IC structure 101 has a convex curvature or a “cry” shape, where solder bridging may occur at an edge region, such as region L2. In the example of FIG. 2C, IC structure 101 has both a convex and concave curvature or an “M” shape, where solder bridging may occur at an intermediate region between the center or edge of the package, such as intermediate region L3. It should be noted that the examples in FIGS. 2A-2C are merely illustrative and not exhaustive. For example, the curvatures or warpage characteristics of an IC structure may be symmetrical or non-symmetrical so that an IC structure with a concave or “smile” curvature may have a low point or region in a location other than a central location as described in the example of FIG. 2A. As such, it is contemplated that the low points or regions may be located at any location along the back side of the routing layer based on any combination of curvatures or warpage characteristics of the IC structure. Also, it should be understood that module substrates may also have curvatures associated with solder bridging. While such module substrate curvatures or warpage characteristics are not illustrated, the same principles apply regarding the standoff distance between the back side of the routing layer and the top side of the module substrate when determining the lowest point or region for a particular electronic module.

Referring back to the example of FIGS. 1A-1B, electronic module 100 may include a plurality of deflectors 160 (e.g., 160A, 160B, 160C, 160D, etc.) located at the low points or regions that are susceptible to solder bridging. In this way, the plurality of deflectors replaces all or at least some of the solder joints in these susceptible locations to mitigate or eliminate solder bridging in such locations. Further, the plurality of deflectors may also provide the added mechanical benefit of reducing compressive stresses on the solder joints that surround the plurality of deflectors. In some instances, it has been shown that during heat sink loading the plurality of deflectors may reduce the compressive stresses on the solder joints that surround the plurality of deflectors by approximately 30%. The plurality of deflectors 160 may include any combination of active and/or passive components, such as integrated passive devices, chiplets, various IP blocks, etc. In an embodiment, the plurality of deflectors may include integrated passive devices, such as capacitor arrays, etc. In instances where the plurality of deflectors includes active and/or passive components, the active and/or passive components may be bonded to back side 121B of routing layer 120 so that such components may perform their respective functions related to IC structure 101, similar to the plurality of deflectors 160A, 160B, 160C illustrated in FIG. 1A. The plurality of deflectors 160 may also include dummy features that may be formed of any suitable material (e.g., polymers, etc.) that will adhere to the module substrate and tolerate the thermal loads associated with thermocompression bonding. In such instances, the dummy feature may be bonded to top side 202 of module substrate 201, similar to the plurality of deflectors 160D, 160E illustrated in FIG. 1B. In addition, the section of back side routing layer 120 directly above the dummy feature may not include solder joints, where the section without solder joints may have a footprint that corresponds to a footprint of the dummy feature. Further, the plurality of deflectors 160 may be located at one or more low points of IC structure 101 and/or one or more low regions that surround the low points. The low point of the IC structure may be defined as the point where the standoff distance between the back side of the routing layer and the top side of the module substrate is lowest, where the IC structure may include multiple low points based on the curvature or warpage characteristic of the IC structure. The low region of an IC structure may be defined as one or more regions that surround the one or more low points where solder joints may still be susceptible to solder bridging. For example, in FIG. 1A, IC structure 101 includes low point P1 and low region R1, where deflector 160B is located at low point P1 and deflectors 160A, 160C are located within region R1. In FIG. 1B, IC structure 101 includes low point P1, where deflectors 160D, 160E are located within region R1.

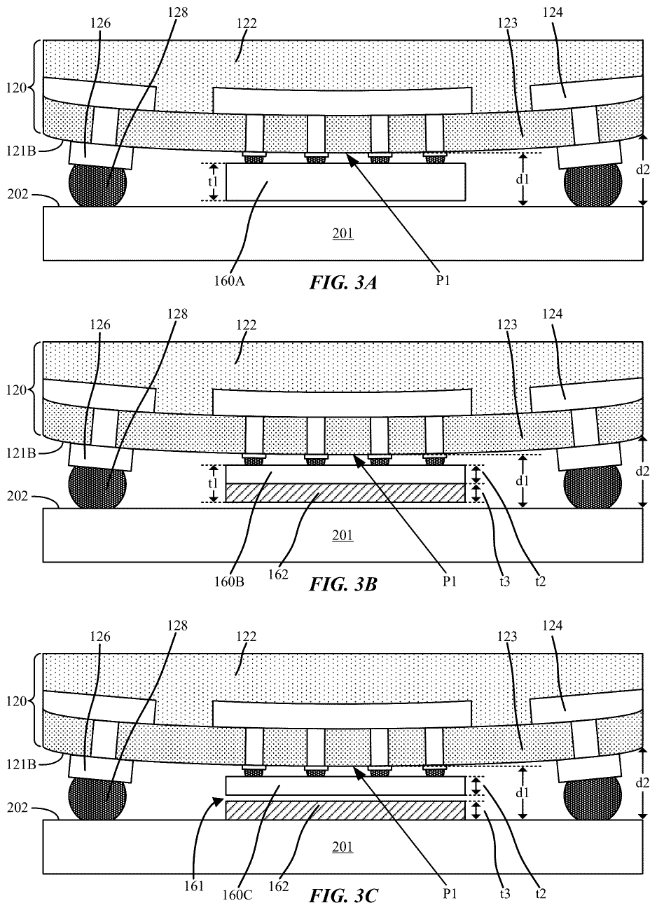

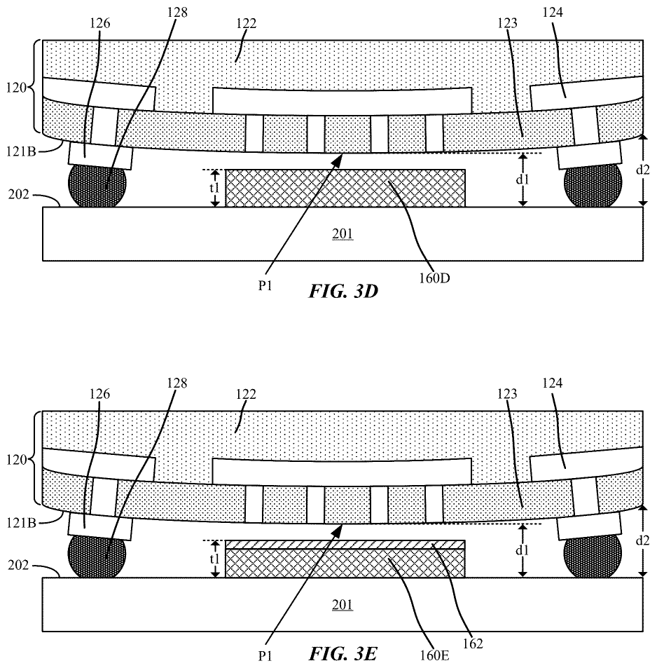

Referring now to FIGS. 3A-3E, FIGS. 3A-C are close-up views of a plurality of deflectors bonded to the back side routing layer of an IC structure similar to the embodiments described in FIG. 1A; FIGS. 3D-E are close-up views of a plurality of deflectors bonded to the top side of a module substrate similar to the embodiments described in FIG. 1B. As shown, IC structure 101 is bonded to top side 202 of module substrate 201, where IC structure 101 includes redistribution lines 124 embedded in dielectric layer 122, passivation layer 123, UBM pads 126 and solder joints 128 similar to FIGS. 1A-1B. Further, the plurality of deflectors 160 may be located at the low point of IC structure 101 and/or a low region that surrounds the low point, where such locations relate to the curvature or warpage characteristics of the IC structure. More specifically, the plurality of deflectors 160 may be located under one or more points or regions where the standoff distance between the back side of the routing layer and the top side of the module substrate is lowest. For example, in FIGS. 3A-3C, deflector 160A is located at low point P1, where the standoff distance d1 at low point P1 is less than the standoff distance d2. Similarly, in FIGS. 3D-3E, deflector 160B is located at low point P1, where the standoff distance d1 at low point P1 is less than the standoff distance d2. It should be noted that the embodiments described in FIGS. 3A-3E include an IC structure with a concave or “smile” curvature. While not illustrated, it is understood that other curvatures (e.g., convex or “cry” curvatures, concave and convex or “M” curvatures, etc.) are also contemplated.

In further reference to FIGS. 3A-3E, the thickness of the plurality of deflectors may further mitigate the risk of solder bridging. For example, during the bonding process (e.g., thermocompression, etc.), the plurality of deflectors may act as a fulcrum that “deflects” the low point of the IC structure away from the module substrate and prevents the low point of the IC structure from collapsing onto the top side of the module substrate, thereby mitigating the risk of solder bridging. In such instances, the thickness of each of the plurality of deflectors may be between 50-80% of the standoff distance between the back side of the routing layer and the top side of the module substrate, although other percentages are contemplated. In some embodiments, the thickness of each of the plurality of deflectors 160 may be uniform. In other embodiments, the thickness of each of the plurality of deflectors 160 may vary based on the standoff distance between the back side of the routing layer and the top side of the module substrate for a particular location of a particular deflector. In this way, each of the plurality of deflectors 160 (e.g., active components, passive components, dummy features, etc.) may have its own optimized thickness based on the curvature or warpage characteristic of the IC structure at a particular low point or within a particular low region where the solder joints may be susceptible to solder bridging.

Referring still to FIGS. 3A-3E, FIG. 3A shows deflector 160A bonded to back side 121B of routing layer 120, where deflector 160A in FIG. 3A is substantially similar to deflector 160A in FIG. 1A. The thickness, t1, of deflector 160A may be greater than the thickness of a conventional integrated passive device, where t1 may be between 50-80% of the standoff distance, d1, between the back side 121B of the routing layer 120 and the top side 202 of the module substrate. FIG. 3B shows deflector 160B bonded to back side 121B of routing layer 120, where deflector 160B in FIG. 3B is substantially similar to deflector 160B in FIG. 1A. Deflector 160B has a thickness, t2, similar to the thickness of a conventional integrated passive device. However, a thin film, such as film 162 in FIG. 3B, may be formed (e.g., laminated) on deflector 160B to mitigate any stress undergone by the deflector itself during the bonding process. In such instances, film 162 may have a thickness, t3, so that the thickness of deflector 160B, t2, and the thickness of film 162, t3, combine for a thickness t1 that is between 50-80% of the standoff distance between back side 121B of routing layer 120 and top side 202 of module substrate 201. FIG. 3C shows deflector 160C bonded to back side 121B of routing layer 120, where deflector 160C in FIG. 3C is substantially similar to deflector 160C in FIG. 1A. In the example of FIG. 3C, film 162 may be formed on top side 202 of module substrate 201 (rather than on the deflector as illustrated in FIG. 3B). In such instances, film 162 may be located directly beneath deflector 160C. Further, an air gap, such as air gap 161 in FIG. 3C, may be present between film 162 formed on top side 202 of module substrate 201 and deflector 160C bonded to back side 121B of routing layer 120. FIG. 3D shows deflector 160D bonded to top side 202 of module substrate 201, where deflector 160D in FIG. 3D is substantially similar to deflector 160D in FIG. 1B. Deflector 160D (e.g., dummy feature) has a thickness, t1, that is between 50-80% of the standoff distance between back side 121B of routing layer 120 and top side 202 of module substrate 201. FIG. 3E shows deflector 160E bonded to top side 202 of module substrate 201, where deflector 160E in FIG. 3E is substantially similar to deflector 160D in FIG. 3D. In the example of FIG. 3E, deflector 160E includes film 162 to mitigate any stress undergone by the deflector itself during the bonding process.

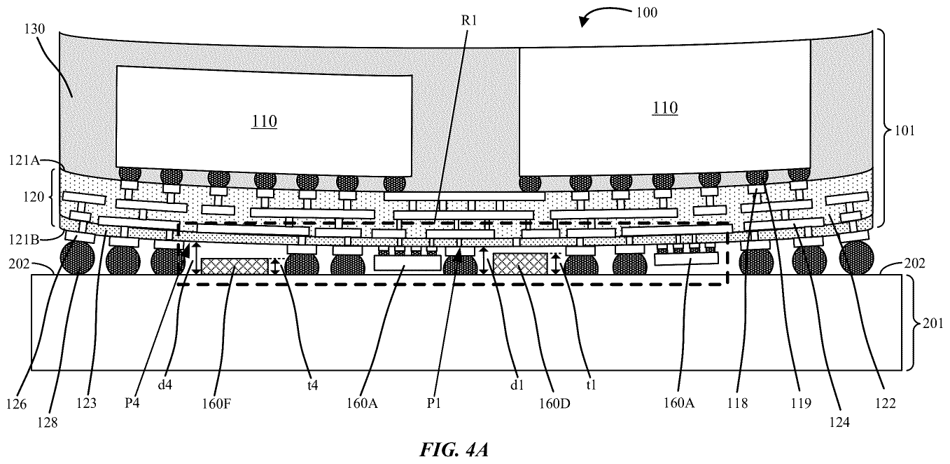

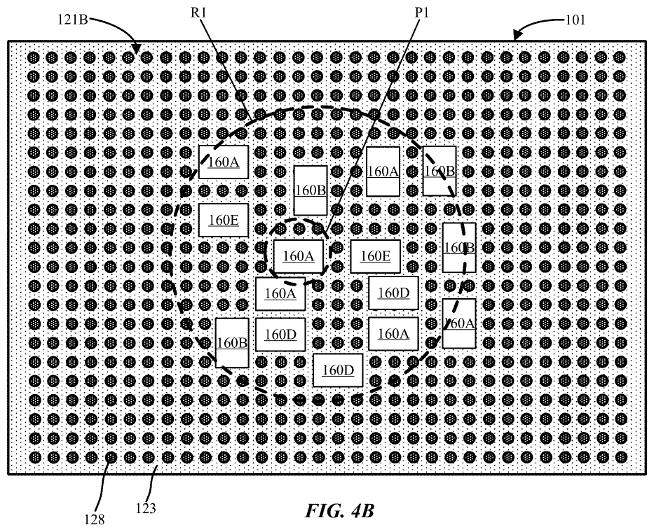

Referring now to FIGS. 4A-4B, FIG. 4A is a schematic cross-sectional side view illustration of electronic module 100 that includes a plurality of deflectors 160 bonded to both IC structure 101 and module substrate 201 in accordance with embodiments; FIG. 4B is a bottom view is of electronic module 100 that includes a plurality of deflectors 160 bonded to both IC structure 101 and module substrate 201 in accordance with embodiments. The embodiment described in FIG. 4A is substantially similar to the embodiment described in FIG. 1A in which the plurality of deflectors is bonded to IC structure 101, and substantially similar to the embodiment described in FIG. 1B in which the plurality of defectors is bonded to module substrate 201, except that the embodiment described in FIG. 4A includes a plurality of deflectors bonded to both IC structure 101 and module substrate 201. In FIG. 4A, electronic module 100 includes IC structure 101 (e.g., system-on-chip (SOC), etc.) mounted to module substrate 201 (e.g., printed circuit board (PCB), etc.) through UBM pads 126 and solder joints 128. In such instances, IC structure 101 may include IC dies 110 bonded to routing layer 120 (e.g., chip first, chip last, hybrid bonded, etc.) and encapsulated by gap fill material 130 (e.g., epoxy molding compound, oxide, etc.). Further, as shown in FIG. 4A, the plurality of deflectors may include deflector 160A (e.g., integrated passive device, etc.) bonded to back side 121B of routing layer 120, as well as deflectors 160D, 160F (e.g., dummy features, etc.) bonded to top side 202 of module substrate 201. In addition, each of the plurality of deflectors 160 may have a different thickness based on the curvature or warpage characteristic of IC structure 101 at a particular location. For example, in FIG. 4A, the distance, d1, between back side 121B of routing layer 120 and top side 202 of module substrate 201 at location P1 is different than the distance, d4, between the back side 121B of routing layer 120 and top side 202 of module substrate 201 at location P4 due to the concave or “smile” curvature of IC structure 101. As such, the thickness, t1, of deflector 160D may be tailored to distance d1, whereas the thickness, t4, of deflector 160F may be tailored to distance d4. In such instances, thickness t1 and t4 may be different since the distances d1 and d4, respectively, are also different.

In reference to FIG. 4B, it should be noted that module substrate 201 is not shown so as to reveal the locations of the plurality of deflectors that would be obscured by module substrate 201 from the bottom view perspective, even though some of the plurality of deflectors may be bonded to module substrate 201 (e.g., 160D, 160E, etc.). As shown in FIG. 4B, electronic module 100 may include both a plurality of deflectors 160 bonded back side 121B of routing layer 120 similar to FIG. 1A (e.g., 160A, 160B, 160C, etc.) as well as a plurality of deflectors bonded to top side 202 of module substrate 201 similar to FIG. 1B (e.g., 160D, 160E, etc.). In addition, the plurality of deflectors 160 may be located at the low point of IC structure 101, such as low point P1, as well as the region that surrounds the low point of IC structure 101, such as low region R1. Further, electronic module 100 may include any combination of the plurality of deflectors 160. For example, electronic module 100 may only require a singular integrated passive device to be mounted to back side 121B of routing layer 120, where the remainder of the plurality of deflectors 160 may include dummy features mounted to top side 202 of module substrate 201 (e.g., 160D, 160E, etc.). Further still, due to the variety curvatures of IC structure 101 (e.g., concave or “smile” curvatures, convex or “cry” curvatures, both concave and convex or “M” curvatures, etc.) and the lack of symmetry associated with such curvatures or warpage characteristics, the low point and its surrounding low region may be located at any point or region along back side 121B of routing layer 120 where the plurality of deflectors 160 may be placed according to the embodiments described.

In utilizing the various aspects of the embodiments, it would become apparent to one skilled in the art that combinations or variations of the above embodiments are possible for mitigating solder bridging with a plurality of deflectors. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic module comprising:
a module substrate;
an integrated circuit (IC) structure mounted to a top side of the module substrate, the IC structure including an integrated circuit (IC) die, a gap fill material that encapsulates the IC die, and a routing layer that includes top side and a back side, wherein the IC die is bonded to the top side of the routing layer and the back side of the routing layer includes an array of solder joints; and
a plurality of deflectors located directly under one or more points or regions where a standoff distance between the back side of the routing layer and the top side of the module substrate is lowest.

2. The electronic module of claim 1, wherein the module substrate is a printed circuit board.

3. The electronic module of claim 1, wherein the IC die is a system-on-chip.

4. The electronic module of claim 1, wherein the region where the standoff distance between the back side of the routing layer and the top side of the module substrate is lowest includes a curvature of the IC structure.

5. The electronic module of claim 4, wherein the curvature is concave.

6. The electronic module of claim 1, wherein a thickness of each of the plurality of deflectors is between 50-80% of the standoff distance between the back side of the routing layer and the top side of the module substrate.

7. The electronic module of claim 1, wherein the plurality of deflectors includes a first deflector bonded to the back side of the routing layer.

8. The electronic module of claim 7, wherein the first deflector is a chiplet.

9. The electronic module of claim 7, wherein the first deflector is an integrated passive device.

10. The electronic module of claim 7, wherein a thin film is formed on the first deflector.

11. The electronic module of claim 7, wherein a thin film is formed on the top side of the module substrate, the thin film being located directly beneath the first deflector.

12. The electronic module of claim 11, wherein an air gap is present between the thin film formed on the top side of the module substrate and the first deflector bonded to the back side of the routing layer.

13. The electronic module of claim 1, wherein the plurality of deflectors includes a second deflector bonded to the top side of the module substrate.

14. The electronic module of claim 13, wherein the second deflector is a dummy feature, the dummy feature comprising a polymer material.

15. The electronic module of claim 13, wherein a section of the back side routing layer located directly above the second deflector does not include solder joints, the section having a footprint that corresponds to a footprint of the second deflector.

16. The electronic module of claim 15, wherein a thin film is formed on the second deflector.

17. The electronic module of claim 1, wherein the plurality of deflectors includes a first deflector bonded to the back side of the routing layer and a second deflector bonded to the top side of the module substrate.

18. The electronic module of claim 17, wherein a first thickness of the first deflector is the same as a second thickness of the second deflector.

19. The electronic module of claim 17, wherein a first thickness of the first deflector is different from a second thickness of the second deflector.

20. The electronic module of claim 19, wherein the first thickness of the first deflector is based on a first standoff distance of a first low point, and the second thickness of the second deflector is based on a second standoff distance of a second low point.

21. The electronic module of claim 17, wherein the plurality of deflectors further includes a third deflector bonded to the top side of the module substrate, the third deflector having a different thickness than the second deflector.
